(19) United States
(12) Patent Application Publication
(10) Pub. No.: US 2025/0351361 A1
(43) Pub. Date: Nov. 13, 2025

(54) MICROELECTRONIC DEVICES INCLUDING BORON-DOPED SEMICONDUCTOR MATERIAL, AND RELATED METHODS AND MEMORY DEVICES

(71) Applicant: Micron Technology, Inc., Boise, ID (US)

(72) Inventors: Zhi Qiang Teo, Singapore (SG); Yuwei Ma, Singapore (SG); Chun Wei Ee, Singapore (SG); Kailing Shih, Singapore (SG)

(21) Appl. No.: 19/171,891

(22) Filed: Apr. 7, 2025

Related U.S. Application Data
(60) Provisional application No. 63/643,729, filed on May 7, 2024.

(51) Int. Cl. H10B 43/35; H01L 25/00; H01L 25/18; H10B 43/27; H10B 80/00; H10N 79/00

(52) U.S. Cl. CPC H10B 43/35; H01L 25/18; H01L 25/50; H10B 43/27; H10B 80/00; H10N 79/00

(57) ABSTRACT

A microelectronic device includes a boron-doped semiconductor material, a stack structure, slot structures, and cell pillar structures. The boron-doped semiconductor material is vertically above a lateral contact material. The stack structure is vertically above the boron-doped semiconductor material and includes blocks horizontally extending in parallel in a first direction and individually having tiers respectively including conductive material and insulative material vertically neighboring the conductive material. The slot structures vertically extend through the stack structure, the boron-doped semiconductor material, and the lateral contact material. The slot structures horizontally alternate with the blocks of the stack structure in a second direction orthogonal to the first direction. The cell pillar structures respectively include semiconductor material in contact with the lateral contact material and vertically extending through each of the lateral contact material, the boron-doped semiconductor material, and the stack structure. Related methods and memory devices are also described.

### CROSS-REFERENCE TO RELATED APPLICATIONS

This application claims the benefit under 35 U.S.C. § 119 (e) of U.S. Provisional Patent Application Ser. No. 63/643,729, filed May 7, 2024, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices, and to related microelectronic devices, memory devices, electronic systems, and additional methods.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in one or more decks (e.g., stack structures) including tiers of conductive structures and dielectric materials. Each vertical memory string may include at least one select device coupled in series to a serial combination of vertically stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

As feature packing densities have increased and margins for formation errors have decreased, conventional methods of forming memory devices (e.g., 3D NAND Flash memory devices) have resulted in undesirable damage that can diminish desired memory device performance, reliability, and durability. For example, conventional methods of forming a stack structure of a memory device (e.g., 3D NAND Flash memory device) using so called “replacement gate” or “gate last” processing, wherein sacrificial structures of a preliminary stack structure are at least partially replaced with the conductive structures, can result in undesirable damage to features (e.g., materials, structures) underlying the preliminary stack structure. Such damage can result in undesirable defects, undesirable reliability, and/or undesirable durability in the memory device including the stack structure formed through such conventional methods.

### BRIEF DESCRIPTION OF THE DRAWINGS

FIGS. 1A through 1L are simplified, partial vertical cross-sectional views illustrating a method of forming a microelectronic device, in accordance with embodiments of the disclosure.

FIG. 2 is a simplified partial cutaway perspective view of a microelectronic device, in accordance with embodiments of the disclosure.

FIG. 3 is a schematic block diagram illustrating an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device, such as 3D NAND Flash memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁻⁴ S/cm (10⁻⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}AS_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, a “semiconductor structure” or a “semiconductor structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

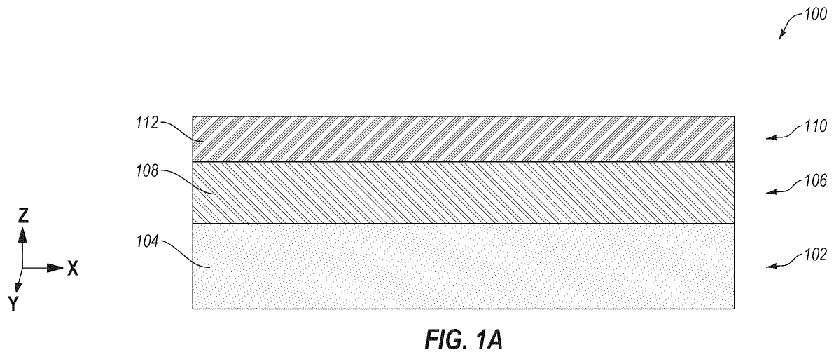

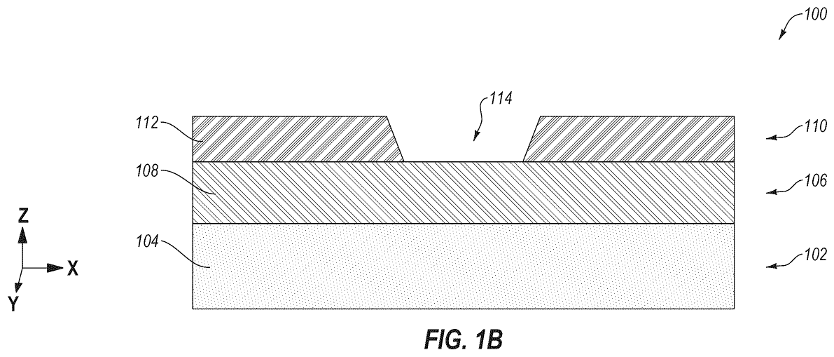

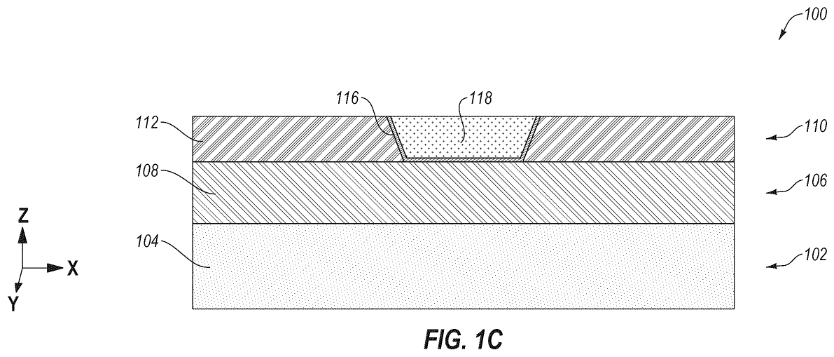

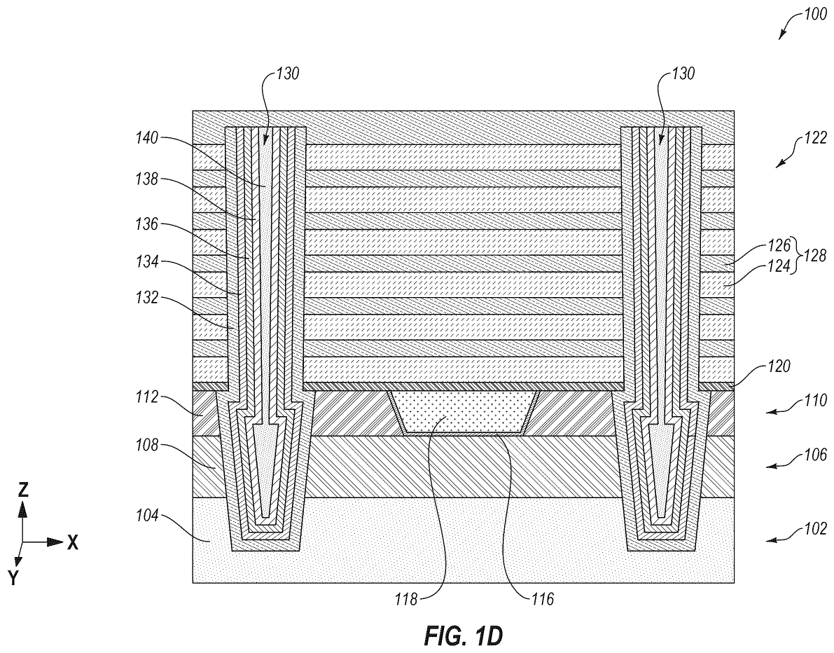

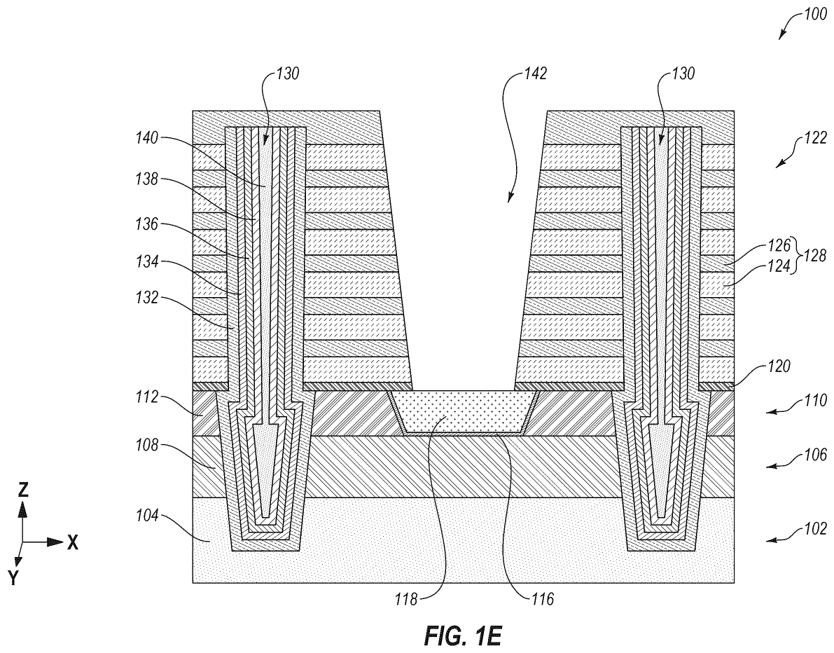

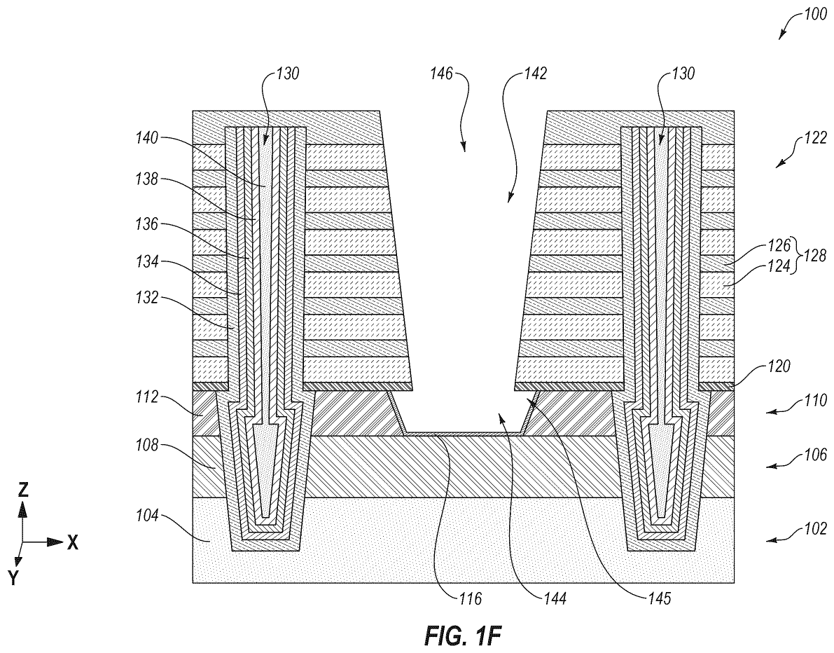

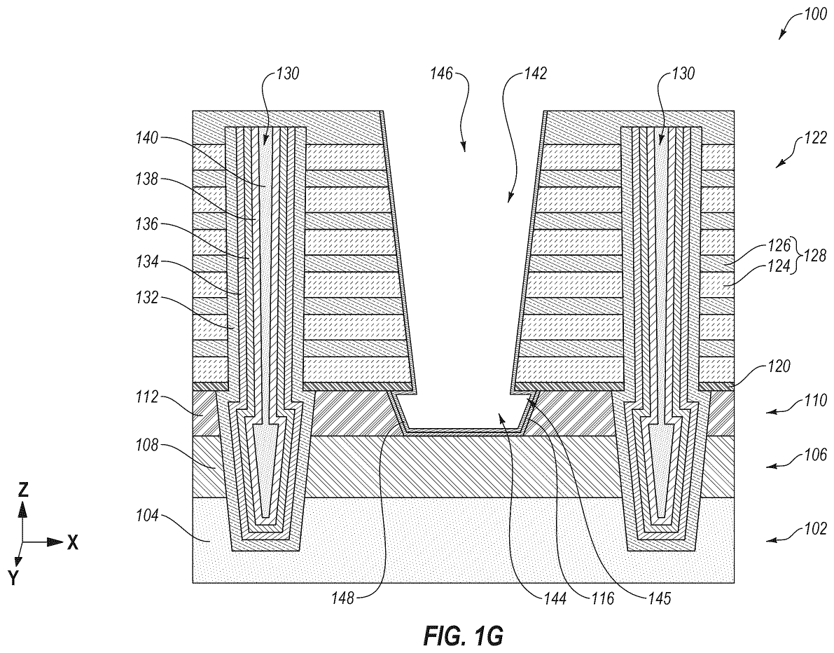

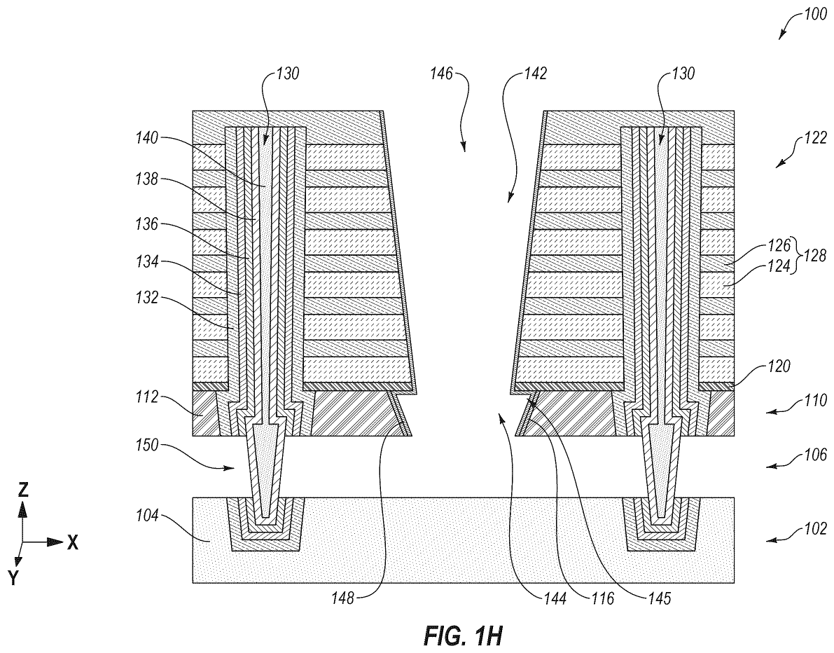

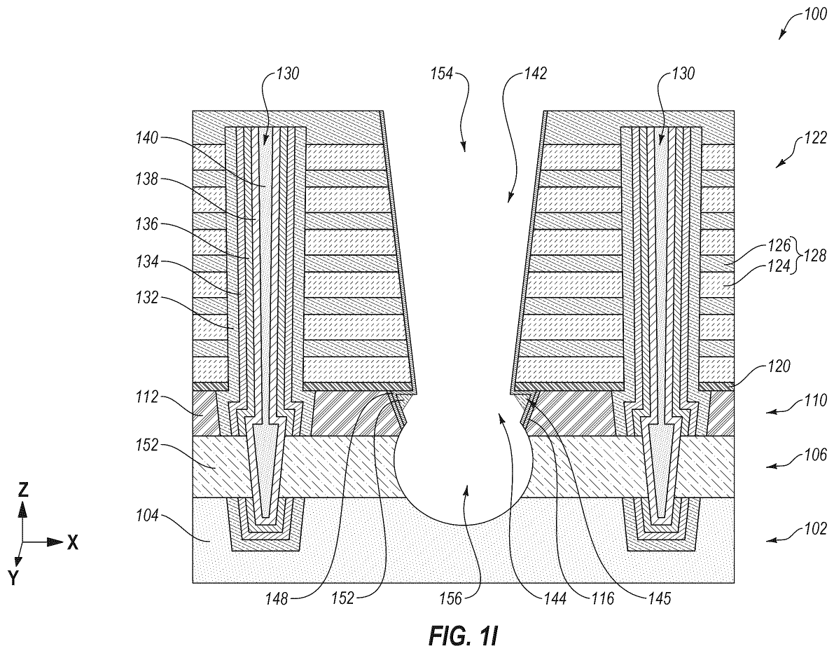

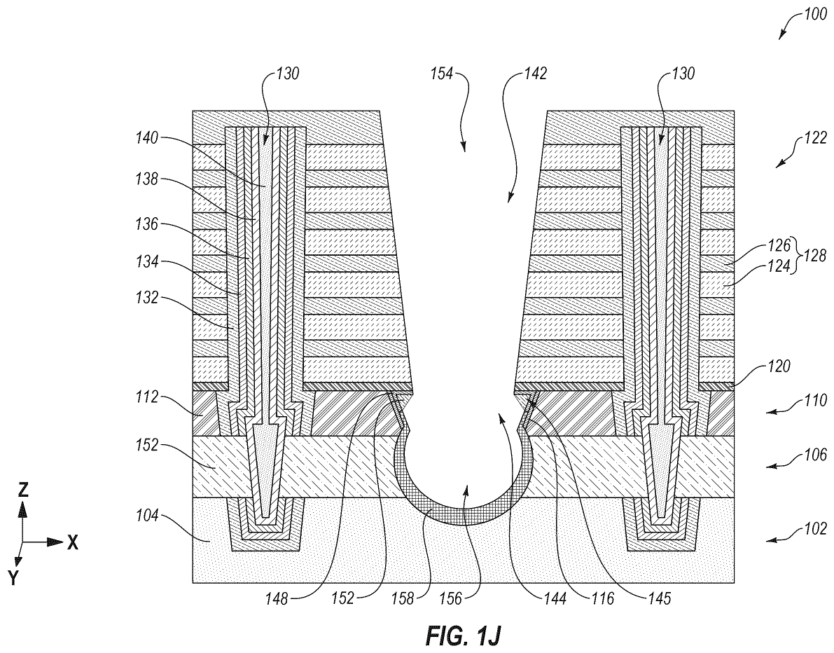

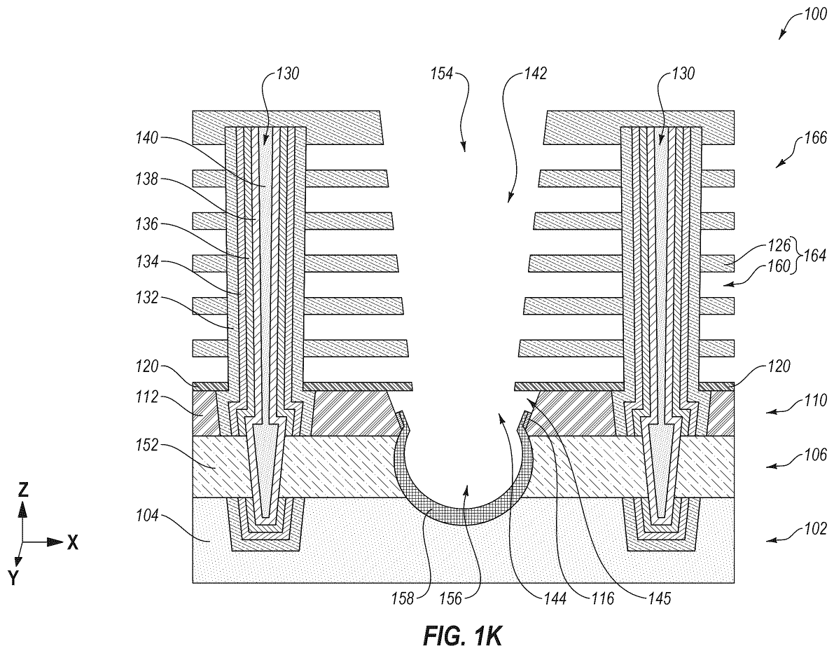

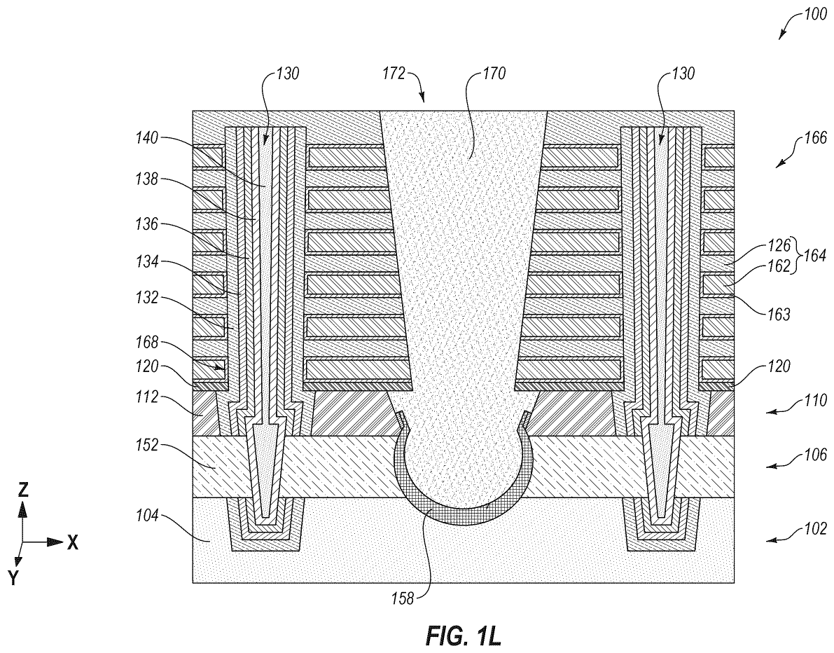

FIGS. 1A through 1L are simplified partial cross-sectional views illustrating embodiments of a method of forming a microelectronic device (e.g., a memory device, such as a 3D NAND Flash memory device). With the description provided below, it will be readily apparent to one of ordinary skill in the art that the methods and structures described herein may be used in various devices and electronic systems.

As shown in FIG. 1A, a microelectronic device structure 100 may be formed to include a semiconductor tier 102, a lateral contact tier 106, and a capping tier 110. The semiconductor tier 102 includes semiconductor material 104. The lateral contact tier 106 vertically overlies the semiconductor tier 102 and includes sacrificial material 108. The capping tier 110 vertically overlies the lateral contact tier 106 and includes boron-doped semiconductor material 112.

The semiconductor material 104 of the semiconductor tier 102 may, for example, be formed of and include one or more of silicon (e.g., monocrystalline silicon and/or polycrystalline silicon), silicon-germanium, germanium, gallium arsenide, a gallium nitride, gallium phosphide, indium phosphide, indium gallium nitride, and aluminum gallium nitride. In some embodiments, the semiconductor material 104 is formed of and includes polycrystalline silicon.

The sacrificial material 108 of the lateral contact tier 106 may be formed of and include material that may be selectively removed relative to additional materials of the microelectronic device structure 100, as described in further detail. The sacrificial material 108 may, for example, be selectively etchable relative to the boron-doped semiconductor material 112 during common (e.g., collective, mutual) exposure to an etchant (e.g., tetramethylammonium hydroxide (TMAH)). As used herein, a material is “selectively etchable” relative to another material if the material exhibits an etch rate that is at least about five times (5×) greater than the etch rate of another material, such as about ten times (10×) greater, about twenty times (20×) greater, or about forty times (40×) greater. As a non-limiting example, the sacrificial material 108 may be formed of and include additional semiconductor material, such as one or more of silicon (e.g., monocrystalline silicon and/or polycrystalline silicon), silicon-germanium, germanium, gallium arsenide, a gallium nitride, gallium phosphide, indium phosphide, indium gallium nitride, and aluminum gallium nitride. In some embodiments, the sacrificial material 108 is formed of and includes polycrystalline silicon.

The boron-doped semiconductor material 112 of the capping tier 110 may be formed of and include further semiconductor material (e.g., one or more of silicon, silicon-germanium, germanium, gallium arsenide, a gallium nitride, gallium phosphide, indium phosphide, indium gallium nitride, and aluminum gallium nitride) doped with boron. In some embodiments, the boron-doped semiconductor material 112 is formed of and includes boron-doped polycrystalline silicon. The boron-doped semiconductor material 112 may have enhanced etch resistance relative to the sacrificial material 108 of the lateral contact tier 106 during mutual exposure to an etchant subsequently employed to remove the sacrificial material 108, as described in further detail below. The boron-doped semiconductor material 112 may, for example, have enhanced etch resistance to TMAH relative to the sacrificial material 108 of the lateral contact tier 106.

An atomic concentration range of boron within the boron-doped semiconductor material 112 may be greater than or equal to about 1.0E18 boron atoms per cubic centimeter (cm³), such as within a range of from about 1.0E15 boron atoms/cm³ to about 5.0E21 boron atoms/cm³, such as from about 1.0E18 boron atoms/cm³ to about 5.0E21 boron atoms/cm³, from about 1.0E20 boron atoms/cm³ to about 5.0E21 boron atoms/cm³, from about 1.0E20 boron atoms/cm³ to about 3.0E21 boron atoms/cm³, or from about 1.0E20 boron atoms/cm³ to about 2.5E21 boron atoms/cm³. In some embodiments, an atomic concentration of boron within the boron-doped semiconductor material 112 is 1.0E15 boron atoms/cm³ to about 2.5E21 boron atoms/cm³. In additional embodiments, an atomic concentration of boron within the boron-doped semiconductor material 112 is about 2.5E21 boron atoms/cm³.

The boron-doped semiconductor material 112 may have a substantially homogeneous distribution of boron therein, or the boron-doped semiconductor material 112 may have a heterogeneous distribution of boron therein. In some embodiments, the boron-doped semiconductor material 112 exhibits a substantially homogeneous distribution of boron therein, such that the boron-doped semiconductor material 112 exhibits a substantially uniform (e.g., even, non-variable) distribution of boron throughout each of the dimensions (e.g., vertical dimension, such as thickness; horizontal dimensions, such as length and width) thereof. For example, amounts (e.g., atomic concentrations) of boron included in the boron-doped semiconductor material 112 may not substantially vary throughout the vertical dimension (e.g., in the Z-direction) and the horizontal dimensions (e.g., in the X-direction and in the Y-direction) of the boron-doped semiconductor material 112. In additional embodiments, the boron-doped semiconductor material 112 exhibits a heterogeneous distribution of boron therein, such that the boron-doped semiconductor material 112 exhibits a substantially non-uniform (e.g., non-even, variable) distribution of the boron throughout one or more of the dimensions (e.g., vertical dimension, such as thickness; horizontal dimensions, such as length and width) thereof. For example, amounts (e.g., atomic concentrations) of boron included in the boron-doped semiconductor material 112 may vary (e.g., increase, decrease) throughout a vertical dimension (e.g., in the Z-direction) and/or one or more horizontal dimensions (e.g., in the X-direction and in the Y-direction) of the boron-doped semiconductor material 112.

The boron-doped semiconductor material 112 may be formed to a desired thickness (e.g., vertical dimension). By way of non-limiting example, the boron-doped semiconductor material may be formed to have a thickness within a range of from about 50 nanometers (nm) to about 100 nm, such as from about 55 nm to about 90 nm, or from about 60 nm to about 80 nm. In some embodiments, the boron-doped semiconductor material 112 is formed to have a thickness of about 80 nm.

The boron-doped semiconductor material 112 of the capping tier 110 may be formed on or over the sacrificial material 108 of the lateral contact tier 106 through an in situ formation (e.g., deposition) process. By way of non-limiting example, the boron-doped semiconductor material 112 may be formed on or over the sacrificial material 108 through a CVD process employing at least one boron-containing precursor gas (e.g., diborane (B₂H₆)) and at least one silicon-containing precursor gas (e.g., silane (SiH₄)).

Relative to other materials conventionally employed as a capping material (e.g., phosphorous-doped semiconductor material, such as phosphorous-doped polycrystalline silicon), the boron-doped semiconductor material 112 may substantially mitigate (e.g., substantially prevent) undesirable damage (e.g., corrosion-based damage) to features (e.g., materials, structures, regions) of the microelectronic device structure 100 during subsequent processing thereof to form a microelectronic device. In addition, the in situ formation of the boron-doped semiconductor material 112 may enhance processing efficiency (e.g., reduce processing acts, such as photolithography acts and/or implantation acts) relative to conventional processes employed to form a conventional capping material (e.g., phosphorous-doped semiconductor material) having enhanced etch-resistance properties.

Referring next to FIG. 1B, portion(s) of the boron-doped semiconductor material 112 of the capping tier 110 may be removed (e.g., etched) to form at least one first trench 114. An individual first trench 114 may vertically extend through a remainder of the boron-doped semiconductor material 112 and to, or partially into, the sacrificial material 108 of the lateral contact tier 106. The first trench 114 may partially expose (e.g., partially uncover) the sacrificial material 108 of the lateral contact tier 106. Horizontal boundaries of an individual first trench 114 may at least partially be defined by side surfaces of a remainder of the boron-doped semiconductor material 112; and a lower vertical boundary of the first trench 114 may be at least partially defined by an upper surface of the sacrificial material 108.

A horizontal position and horizontal dimensions of an individual first trench 114 may be selected at least partially based on desired horizontal positions and desired horizontal dimensions of additional features (e.g., materials, structures, devices) to subsequently be formed at least partially over the remainder of the boron-doped semiconductor material 112, as described in further detail below. By way of non-limiting example, as described in further detail below, the first trench 114 may be formed at a horizontal position of (e.g., in the X-direction), and may have horizontal dimensions (e.g., in the X-direction and in the Y-direction) corresponding to, those of a slot (e.g., slit) to be formed through a subsequently formed stack structure to divide the stack structure into multiple blocks.

Referring next to FIG. 1C, a first dielectric liner 116 and an etch stop structure 118 may respectively be formed within the first trench 114 (FIG. 1B). The first dielectric liner 116 may be formed on or over, and may substantially cover, surfaces of the sacrificial material 108 and the boron-doped semiconductor material 112 defining boundaries (e.g., a lower vertical boundary, horizontally boundaries) of the first trench 114 (FIG. 1B). The etch stop structure 118 may be formed on or over, and may substantially cover, surfaces of the first dielectric liner 116 within the first trench 114 (FIG. 1B). The first dielectric liner 116 may be interposed between the etch stop structure 118 and each of the sacrificial material 108 and the boron-doped semiconductor material 112. The first dielectric liner 116 and the etch stop structure 118 may together substantially fill the first trench 114 (FIG. 1B) and may respectively be vertically positioned with the capping tier 110 of the microelectronic device structure 100. Uppermost surfaces of the first dielectric liner 116 and the etch stop structure 118 may be substantially coplanar with an uppermost surface of the boron-doped semiconductor material 112 of the capping tier 110.

The first dielectric liner 116 may be formed of and include at least one dielectric material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the first dielectric liner 116 is formed of and includes SiOₓ (e.g., SiO₂). In addition, the first dielectric liner 116 may be formed to a desired thickness, such as a thickness within a range of from about 5 nm to about 30 nm, from about 5 nm to about 20 nm, from about 5 nm to about 10 nm, or from about 5 nm to about 8 nm. In some embodiments, the thickness of the first dielectric liner 116 is within a range of from about 5 nm to about 8 nm.

The etch stop structure 118 may be formed of and include at least one etch stop material having relatively enhanced resistance to one or more etchants employed in subsequent etching acts to form one or more openings vertically extending through a preliminary stack structure later formed over the etch stop structure 118, as described in further detail below. As a non-limiting example, the etch stop structure 118 may be formed of and include at least one metallic material. In some embodiments, the etch stop structure 118 is formed of and includes W.

Referring next to FIG. 1D, isolation material 120 may be formed over the capping tier 110 (including the boron-doped semiconductor material 112, the first dielectric liner 116, and the etch stop structure 118 thereof), and a preliminary stack structure 122 may be formed on or over the isolation material 120. In addition, cell pillar structures 130 may be formed to vertically extend through each of the preliminary stack structure 122, the isolation material 120, the boron-doped semiconductor material 112 of the capping tier 110, and the sacrificial material 108 of the lateral contact tier 106, and into the semiconductor material 104 of the semiconductor tier 102. The cell pillar structures 130 may respectively be horizontally offset from the etch stop structure 118 in the X-direction.

As shown in FIG. 1D, the isolation material 120 may be formed on or over, and may substantially cover, uppermost surfaces of the boron-doped semiconductor material 112, the first dielectric liner 116, and the etch stop structure 118 of the capping tier 110. The isolation material 120 may be formed of and include insulative material. By way of non-limiting example, the isolation material 120 may be formed of and include one or more of at least one dielectric oxide material, at least one dielectric oxynitride material, at least one dielectric oxycarbide material, at least one hydrogenated dielectric oxycarbide material, and at least one dielectric carboxynitride material. In some embodiments, the isolation material 120 is formed of and includes dielectric oxide material, such as SiOₓ (e.g., SiO₂). The isolation material 120 may be substantially homogeneous, or the isolation material 120 may be heterogeneous.

The preliminary stack structure 122 may be formed on or over, and may substantially cover, an uppermost surface of the isolation material 120. The preliminary stack structure 122 may be formed to include a vertically alternating (e.g., in the Z-direction) sequence of additional sacrificial material 124 and insulative material 126 arranged in tiers 128. An individual tier 128 of the preliminary stack structure 122 may include the additional sacrificial material 124 vertically neighboring the insulative material 126. The preliminary stack structure 122 may be formed to include any desired number of the tiers 128, such as greater than or equal to sixteen (16) of the tiers 128, greater than or equal to thirty-two (32) of the tiers 128, greater than or equal to sixty-four (64) of the tiers 128, greater than or equal to one hundred and twenty-eight (128) of the tiers 128, or greater than or equal to two hundred and fifty-six (256) of the tiers 128.

The additional sacrificial material 124 of the tiers 128 of the preliminary stack structure 122 may be formed of and include at least one material (e.g., at least one insulative material) that may be selectively removed relative at least to the insulative material 126, the boron-doped semiconductor material 112, and the isolation material 120. A material composition of the additional sacrificial material 124 is different than material compositions of the insulative material 126, the boron-doped semiconductor material 112, and the isolation material 120. In some embodiments, the additional sacrificial material 124 is formed of and includes dielectric nitride material, such as SiN_{y} (e.g., Si₃N₄). The additional sacrificial material 124 and the sacrificial material 108 may, for example, be selectively etchable relative to the insulative material 126, the boron-doped semiconductor material 112, and the isolation material 120 during common exposure to a wet etchant including H₃PO₄. In additional embodiments, the additional sacrificial material 124 is formed of and includes polycrystalline silicon. The additional sacrificial material 124 may, for example, be selectively etchable relative to the insulative material 126, the boron-doped semiconductor material 112, and the isolation material 120 during common exposure to a wet etchant including TMAH. For an individual tier 128, the additional sacrificial material 124 thereof may be substantially homogeneous, or the additional sacrificial material 124 thereof may be heterogeneous.

The insulative material 126 of the tiers 128 of the preliminary stack structure 122 may be formed of and include at least one dielectric material, such as one or more of at least one dielectric oxide material, at least one dielectric nitride material, at least one dielectric oxynitride material, and at least one dielectric carboxynitride material. A material composition of the insulative material 126 may be different than the material composition of the additional sacrificial material 124 of the tiers 128 of the preliminary stack structure 122. The material composition of the insulative material 126 may be substantially the same as a material composition of the isolation material 120, or the material composition of the insulative material 126 may be different than the material composition of the isolation material 120. In some embodiments, the insulative material 126 is formed of and includes dielectric oxide material, such as SiOₓ (e.g., SiO₂). For an individual tier 128, the insulative material 126 thereof may be substantially homogeneous, or the insulative material 126 thereof may be heterogeneous.

Still referring to FIG. 1D, the cell pillar structures 130 may be formed and positioned within horizontal areas of the preliminary stack structure 122 designated for memory array regions of subsequently formed blocks of a microelectronic device of the disclosure. For an individual cell pillar structure 130, an upper portion thereof may vertically extend through the tiers 128 of the preliminary stack structure 122 and the isolation material 120; and a lower portion thereof, continuous with the upper portion, may vertically extend through the boron-doped semiconductor material 112 of the capping tier 110 and the sacrificial material 108 of the lateral contact tier 106, and into the semiconductor material 104 of the semiconductor tier 102. The lower portion of the cell pillar structure 130 may terminate within the semiconductor material 104 of the semiconductor tier 102. As shown in FIG. 1D, for an individual cell pillar structure 130, an upper end of the lower portion thereof may outwardly horizontally project (e.g., in the X-direction, in the Y-direction) from a lower end of the upper portion thereof. A horizontal cross-sectional area of the lower portion of the cell pillar structure 130 at or proximate the upper end of the lower portion may be greater than at least one (e.g., any) horizontal cross-sectional area of the upper portion of cell pillar structure 130, such as a horizontal cross-sectional area of the upper portion at or proximate the lower end of the upper portion. The lower portion of the cell pillar structure 130 may taper from a relatively larger horizontal cross-sectional area at or proximate the upper end thereof to a relatively smaller horizontal cross-sectional area at or proximate a lower end thereof.

The cell pillar structures 130 may respectively be formed of and include a stack of materials. By way of non-limiting example, each of the cell pillar structures 130 may be formed to include a charge-blocking material 132, such as first dielectric oxide material (e.g., SiOₓ, such as SiO₂; AlOₓ, such as Al₂O₃); a charge-trapping material 134, such as a dielectric nitride material (e.g., SiN_{y}, such as Si₃N₄); a tunnel dielectric material 136, such as a second oxide dielectric material (e.g., SiOₓ, such as SiO₂); a channel material 138, such as a semiconductor material (e.g., silicon, such as polycrystalline Si); and a dielectric fill material 140 (e.g., dielectric oxide, dielectric nitride, air). The charge-blocking material may be formed on or over, and may substantially cover, surfaces of the microelectronic device structure 100 defining boundaries (e.g., horizontal boundaries, lower vertical boundaries) of the cell pillar structures 130, such as surfaces of the insulative material 126 and the additional sacrificial material 124 of the tiers 128 of the preliminary stack structure 122, as well as surfaces of the isolation material 120, the isolation material 120, the boron-doped semiconductor material 112, the sacrificial material 108, and the semiconductor material 104. The charge-trapping material 134 may be formed on or over, and may substantially cover, inner surfaces of the charge-blocking material 132. The tunnel dielectric material 136 may be formed on or over, and may substantially cover, inner surfaces of the charge-trapping material 134. The channel material 138 may be formed on or over, and may substantially cover, inner surfaces of the tunnel dielectric material 136. The dielectric fill material may be formed on or over, and may substantially cover, inner surfaces of the channel material 138.

Referring next to FIG. 1E, portions of at least the preliminary stack structure 122 and the isolation material 120 at least partially (e.g., substantially) horizontally overlapping (e.g., in the X-direction, in the Y-direction) a horizontal area of the etch stop structure 118 may be removed to form at least one slot 142 (e.g., slit, opening, trench). An individual slot 142 may vertically extend through the preliminary stack structure 122 and the isolation material 120, and to or into a respective etch stop structure 118. An individual slot 142 may divide (e.g., partition) the preliminary stack structure 122 into multiple preliminary blocks horizontally separated from one another in the X-direction by the slot 142 and horizontally extending in parallel with one another in the Y-direction.

Referring next to FIG. 1F, the etch stop structure 118 (FIG. 1E) may be selectively removed (e.g., selectively exhumed) by way of the slot 142 to form a second trench 144. The second trench 144 may be vertically positioned within the capping tier 110. Horizontal boundaries and a lower vertical boundary (e.g., a lower end) of the second trench 144 may be defined by inner surfaces of the first dielectric liner 116. In addition, an upper vertical boundary (e.g., an upper end) of the second trench 144 may be partially defined by a lower surface of the isolation material 120. As shown in FIG. 1F, the second trench 144 may be integral and continuous with the slot 142. Accordingly, the slot 142 and the second trench 144 may together effectively form an elongated slot 146 (e.g., an extended slot, an enlarged slot). The elongated slot 146 may include an upper portion including the slot 142, and a lower portion including the second trench 144.

Referring next to FIG. 1G, a second dielectric liner 148 may be formed on or over surfaces defining the elongated slot 146 (including the slot 142 and the second trench 144 thereof). The second dielectric liner 148 may be formed on or over, and may substantially cover, surfaces of the preliminary stack structure 122 and the isolation material defining the upper portion of the elongated slot 146 (and, hence, the slot 142); and may also be formed on or over, and may substantially cover, inner surfaces of the first dielectric liner 116 defining the lower portion of the elongated slot 146 (and, hence, the second trench 144). An upper portion of the second dielectric liner 148 within the upper portion of the elongated slot 146 (and, hence, within the slot 142) may be integral and continuous with a lower portion of the second dielectric liner 148 within the lower portion of the elongated slot 146 (and, hence, within the second trench 144). As shown in FIG. 1G, the second dielectric liner 148 may be substantially confined within the elongated slot 146.

The second dielectric liner 148 may be formed of and include one or more dielectric materials having different etch selectivity than the sacrificial material 108 of the lateral contact tier 106. In addition, at least one dielectric material of the second dielectric liner 148 may have different etch selectivity than the additional sacrificial material 124 of the tiers 128 of the preliminary stack structure 122. By way of non-limiting example, the second dielectric liner 148 may be formed of and include one or more of at least one dielectric oxide material, at least one dielectric nitride material, at least one dielectric oxynitride material, and at least one dielectric carboxynitride material. The second dielectric liner 148 may be substantially homogeneous, or the second dielectric liner 148 may be heterogeneous. In some embodiments, the second dielectric liner 148 comprises a stack of at least two (2) different dielectric materials. For example, the second dielectric liner 148 may comprise a stack including dielectric oxide material (e.g., SiOₓ, such as SiO₂), dielectric nitride material (e.g., SiN_{y}, such as Si₃N₄) on or over the dielectric oxide material, and additional dielectric oxide material (e.g., additional SiOₓ, such as additional SiO₂) on or over the dielectric nitride material. In some embodiments, the second dielectric liner 148 comprises a stack including SiO₂, Si₃N₄ on the SiO₂, and additional SiO₂ on the Si₃N₄. In addition, the second dielectric liner 148 may be formed to a desired thickness, such as a thickness within a range of from about 5 nm to about 20 nm, such as from about 5 nm to about 15 nm, from about 5 nm to about 10 nm. In some embodiments, the thickness of the second dielectric liner 148 is within a range of from about 5 nm to about 10 nm.

Referring next to FIG. 1H, portions of the second dielectric liner 148 and the first dielectric liner 116 at the lower vertical boundary (e.g., lower end, bottom) of the elongated slot 146 may be removed (e.g., through a so-called “punch-through” etch) to partially expose the sacrificial material 108 (FIG. 1G) of the lateral contact tier 106, and then the sacrificial material 108 (FIG. 1G) and portions of the cell pillar structures 130 within the lateral contact tier 106 may be selectively removed (e.g., selectively exhumed), by way of the elongated slot 146, to form a void space 150 (e.g., cavity, gap) within the lateral contact tier 106. As shown in FIG. 1H, within the lateral contact tier 106, portions of the charge-blocking material 132, the charge-trapping material 134, and the tunnel dielectric material 136 of respective cell pillar structures 130 may be removed, while substantially maintaining the channel material 138 and the dielectric fill material 140 of the respective cell pillar structures 130. Accordingly, within the lateral contact tier 106, the void space 150 may horizontally extend to and expose portions of the channel material 138 of the cell pillar structures 130. The void space 150 within the lateral contact tier 106 may be integral and continuous with the elongated slot 146.

During the formation of the void space 150 within the lateral contact tier 106, the material composition of the boron-doped semiconductor material 112 of the capping tier 110 may mitigate undesirable removal thereof. Conventional methods employing a different capping material within a capping tier, such as phosphate-doped polycrystalline silicon, can suffer from undesirable removal of the capping material during the process of exhuming a sacrificial material thereunder. Such undesirable capping material removal may, for example, be promoted or facilitated, at least in part, by horizontal misalignment (sometimes referred to as “fall off”) of an equivalent to the slot 142 relative to an underlying etch stop structure. Such misalignment may result in undesirable removal of portions of the second dielectric liner 148 and the first dielectric liner 116 during punch-through etching that facilitates access to (e.g., undesirable exposure of) the conventional capping material. Such access, in combination with the relatively decreased etch resistance of the conventional capping material (as compared to the boron-doped semiconductor material 112 of the disclosure), may undesirably facilitate at least partial removal of the conventional capping material during removal of the underlying sacrificial material. Undesired gaps resulting from such removal of the conventional capping material may be difficult or even impossible to resolve. However, the material composition of the boron-doped semiconductor material 112 of the capping tier 110 may prevent the undesirable removal of the boron-doped semiconductor material 112 (and, hence, the formation of undesirable gaps in the capping tier 110) during the formation of the void space 150, even if, as-formed, the slot 142 is horizontally misaligned relative to the etch stop structure 118 (FIG. 1E) in a manner similar to that described above.

Referring next to FIG. 1I, the void space 150 (FIG. 1H) within the lateral contact tier 106 may be filled with lateral contact material 152 by way of the elongated slot 146 (FIG. 1H). Thereafter, an additional material removal process may be performed to remove portions of the lateral contact material 152 on or over inner surfaces of a remaining portion of the second dielectric liner 148, as well as additional portions of the lateral contact material 152 within the lateral contact tier 106 and portions of the semiconductor material 104 within the semiconductor tier 102 that respectively horizontally overlap (e.g., in the X-direction and in the Y-direction) the elongated slot 146 (FIG. 1H). The removal of the additional portions of the lateral contact material 152 within the lateral contact tier 106 and the portions of the semiconductor material 104 within the semiconductor tier 102 may form a third trench 156 vertically extending from the second trench 144, through a remaining portion of the lateral contact material 152 within the lateral contact tier 106, and into a remaining portion of the semiconductor material 104 within the semiconductor tier 102. The third trench 156 may have an arcuate (e.g., curved) vertical cross-sectional shape, including boundaries partially defined by surfaces of the lateral contact material 152 of the lateral contact tier 106 and the semiconductor material 104 of the semiconductor tier 102. As shown in FIG. 1I, the third trench 156 may be integral and continuous with the second trench 144 and the slot 142. Accordingly, the slot 142, the second trench 144, and the third trench 156 may together effectively form a further elongated slot 154 (e.g., a further extended slot, a further enlarged slot). The further elongated slot 154 may include an upper portion including the slot 142, a middle portion including the second trench 144, and a lower portion including the third trench 156.

The lateral contact material 152 may be formed of and include at least one further semiconductor material, such as one or more of silicon (e.g., polycrystalline silicon), silicon-germanium, germanium, gallium arsenide, a gallium nitride, gallium phosphide, indium phosphide, indium gallium nitride, and aluminum gallium nitride. In some embodiments, the lateral contact material 152 is formed of and includes polycrystalline silicon. As shown in FIG. 1J, within the lateral contact tier 106, the lateral contact material 152 may horizontally extend to and contact (e.g., physically contact, electrically contact) the channel material 138 of respective ones of the cell pillar structures 130.

During the removal of the lateral contact material 152 from the inner surfaces of the remaining portion of the second dielectric liner 148, portions of the lateral contact material 152 located proximate to upper corners 145 of the second trench 144 may be difficult to remove. The upper corners 145 of the second trench 144 may be defined as locations wherein upper vertically boundaries (e.g., upper ends) of the second trench 144 intersect horizontal boundaries of the second trench 144. The upper corners 145 of the second trench 144 may respectively exhibit an acute angle that can pose challenges for the removal of portions of the lateral contact material 152 proximate thereto. Accordingly, as shown in FIG. 1I, portions of the lateral contact material 152 located proximate to the upper corners 145 of the second trench 144 may remain following the formation of the further elongated slot 154.

Referring next to FIG. 1J, portions of the second dielectric liner 148 exposed within the further elongated slot 154 may be removed, and a third dielectric liner 158 may be formed to cover each of surfaces of the semiconductor material 104 of the semiconductor tier 102 and surfaces of the lateral contact material 152 of the lateral contact tier 106 exposed by the further elongated slot 154. As shown in FIG. 1J, due to portions of the lateral contact material 152 remaining proximate the upper corners 145 of the second trench 144 (e.g., middle portion of the further elongated slot 154), portions of the second dielectric liner 148 covered by the remaining portions of the lateral contact material 152 (and, hence, at or proximate the upper corners 145 of the second trench 144) may not be removed. The remaining portions of the lateral contact material 152 and the second dielectric liner 148 proximate the upper corners 145 of the second trench 144 may vertically overlie uppermost boundaries of the third dielectric liner 158.

The third dielectric liner 158 may be employed (e.g., serve) as a barrier material to protect (e.g., mask) the semiconductor material 104 of the semiconductor tier 102 and the lateral contact material 152 of the lateral contact tier 106 from removal during subsequent processing acts (e.g., subsequent replacement gate processing acts, such as subsequent wet etching acts), as described in further detail below. The third dielectric liner 158 may be formed on or over, and may substantially cover, surfaces of the semiconductor material 104 of the semiconductor tier 102 and the lateral contact material 152 of the lateral contact tier 106 defining the third trench 156 (e.g., middle portion of the further elongated slot 154), as well as surfaces of the first dielectric liner 116 and/or the boron-doped semiconductor material 112 not covered by remaining portions of the second dielectric liner 148 within the capping tier 110. As shown in FIG. 1J, the third dielectric liner 158 may vertically terminate below the remaining portions of the second dielectric liner 148.

The third dielectric liner 158 may be formed of and include at least one dielectric material having different etch selectivity than the additional sacrificial material 124 of the tiers 128 of the preliminary stack structure 122. The third dielectric liner 158 may, for example, have etch selectively substantially similar to that of the insulative material 126 of the tiers 128 of the preliminary stack structure 122. By way of non-limiting example, the third dielectric liner 158 may be formed of and include one or more of at least one dielectric oxide material, at least one dielectric oxynitride material, and at least one dielectric carboxynitride material. The third dielectric liner 158 may be substantially homogeneous, or the third dielectric liner 158 may be heterogeneous. In some embodiments, the third dielectric liner 158 is formed of and includes dielectric oxide material, such as SiOₓ (e.g., SiO₂). The third dielectric liner 158 may be formed to have a desired thickness capable of protecting the semiconductor material 104 of the semiconductor tier 102 and the lateral contact material 152 of the lateral contact tier 106 during the subsequent processing acts (e.g., subsequent replacement gate processing acts, such as subsequent etching acts). As a non-limiting example, the third dielectric liner 158 may have a thickness within a range of from about 15 nm to about 100 nm, such as from about 20 nm to about 80 nm, from about 20 nm to about 60 nm, from about 20 nm to about 40 nm, or from about 25 nm to about 35 nm. In some embodiments, the thickness of the third dielectric liner 158 is within a range of from about 25 nm to about 35 nm.

Referring next to FIG. 1K, the microelectronic device structure 100 may be subjected to an additional material removal process (e.g., a wet etching process), as part of so-called “replacement gate” processing (also referred to as “gate last” processing), to selectively remove the additional sacrificial material 124 (FIG. 1J) of the tiers 128 of the preliminary stack structure 122. As shown in FIG. 1K, the removal of the additional sacrificial material 124 (FIG. 1J) may result in the formation of additional void spaces 160 vertically alternating with the insulative material 126. Following the processing stage of FIG. 1K, the tiers 128 may individually include an additional void space 160, and insulative material 126 vertically neighboring the additional void space 160. The additional void spaces 160 may subsequently be filled with conductive material, as described in further detail below.

The additional material removal process may include treating the microelectronic device structure 100 with at least one wet etchant formulated to selectively remove portions of the additional sacrificial material 124 (FIG. 1J) of the tiers 128 exposed by the further elongated slot 154. By way of non-limiting example, depending on material compositions of the additional sacrificial material 124 (FIG. 1J), the wet etchant may one or more of TMAH, H₃PO₄, sulfuric acid (H₂SO₄), hydrochloric acid (HCl), nitric acid (HNO₃), and another material. In some embodiments wherein the additional sacrificial material 124 (FIG. 1J) includes dielectric nitride material (e.g., SiN_{y}, such as Si₃N₄), the additional sacrificial material 124 is selectively removed using a wet etchant comprising H₃PO₄. In additional embodiments wherein the additional sacrificial material 124 (FIG. 1J) includes polycrystalline silicon, the additional sacrificial material 124 (FIG. 1J) is selectively removed using a wet etchant comprising TMAH.

Still referring to FIG. 1K, within the capping tier 110, the additional material removal process may also remove remaining portions of the lateral contact material 152 (FIG. 1J), the second dielectric liner 148 (FIG. 1J), and the first dielectric liner 116 at or proximate the upper corners 145 of the second trench 144. The removal of remaining portions of the lateral contact material 152 (FIG. 1J), the second dielectric liner 148 (FIG. 1J), and the first dielectric liner 116 at or proximate the upper corners 145 of the second trench 144 may expose (e.g., uncover) portions of the boron-doped semiconductor material 112 within the capping tier 110. As shown in FIG. 1K, portions of the first dielectric liner 116 and the third dielectric liner 158 may remain within the capping tier 110 following the additional material removal process.

During the additional material removal process, the material composition of the boron-doped semiconductor material 112 of the capping tier 110 may mitigate undesirable removal thereof. Conventional methods employing a different capping material within a capping tier, such as phosphate-doped polycrystalline silicon, can suffer from undesirable removal of the capping material during the process of removing sacrificial material of tiers of a preliminary stack structure thereover. Such undesirable capping material removal may, for example, be promoted or facilitated, at least in part, by a so-called “corner attack” of the capping material at or proximate equivalents to the upper corners 145 of the second trench 144. Such corner attack may result from the absence of an equivalent to the third dielectric liner 158 at or proximate the equivalents to the upper corners 145 of the second trench 144. Such corner attack, in combination with the relatively decreased etch resistance of the conventional capping material (as compared to the boron-doped semiconductor material 112 of the disclosure), may undesirably facilitate at least partial removal of the conventional capping material during removal of the sacrificial material of the tiers of the preliminary stack structure thereover. Undesired gaps resulting from such removal of the conventional capping material may be difficult or even impossible to resolve. However, the material composition of the boron-doped semiconductor material 112 of the capping tier 110 may prevent the undesirable removal of the boron-doped semiconductor material 112 (and, hence, the formation of undesirable gaps in the capping tier 110) during the formation of the additional void spaces 160 within the preliminary stack structure 122, even if, the boron-doped semiconductor material 112 is subject to corner attack at or proximate the upper corners 145 of the second trench 144.

Referring next to FIG. 1L, the additional void spaces 160 (FIG. 1K) within the preliminary stack structure 122 (FIG. 1K) may be filled with conductive material 162 by way of the further elongated slot 154 (FIG. 1K) to convert the preliminary stack structure 122 (FIG. 1K) into a stack structure 166. The stack structure 166 may include a vertically alternating (e.g., in the Z-direction) sequence of the conductive material 162 and remaining portions of the insulative material 126 arranged in tiers 164. An individual tier 164 of the stack structure 166 may include the conductive material 162, and the insulative material 126 vertically neighboring the conductive material 162. In addition, following the formation of the stack structure 166, remaining portions of the further elongated slot 154 (including remaining portions of the slot 142, the second trench 144, and the third trench 156 thereof) (FIG. 1K) may be filled (e.g., substantially filled) with at least one additional dielectric fill material 170 to form a slot structure 172.

The conductive material 162 of the tiers 164 of the stack structure 166 may comprise at least one conductive material suitable for use within access line structures (e.g., local access line structures, local word line structures) and select gate structures (e.g., lower select gate structures, such as source-side select gate (SGS) structures; upper select gate structures, such as drain-side select gate (SGD) structures) of a microelectronic device of the disclosure. In some embodiments, the conductive material 162 of the tiers 164 of the stack structure 166 is formed of and includes W. In addition, optionally, for an individual tier 164 of the stack structure 166, at least one liner material 163 (e.g., at least one insulative liner material, at least one conductive liner material) may be formed around the conductive material 162 thereof. The liner material 163 may, for example, be formed of and include one or more of a metal (e.g., titanium, tantalum), an alloy, a metal nitride (e.g., tungsten nitride, titanium nitride, tantalum nitride), and a metal oxide (e.g., aluminum oxide). In some embodiments, the liner material 163 comprises at least one additional conductive material employed as a seed material for the formation of the conductive material. In some embodiments, the liner material 163 comprises titanium nitride (TiNₓ, such as TiN). In further embodiments, the liner material 163 further includes aluminum oxide (AlOₓ, such as Al₂O₃). As a non-limiting example, AlOₓ (e.g., Al₂O₃) may be formed directly adjacent the insulative material 126, TiNₓ (e.g., TiN) may be formed directly adjacent the AlOₓ, and W may be formed directly adjacent the TiNₓ.

Still referring to FIG. 1L, intersections of the cell pillar structures 130 and the conductive material 162 (inclusive of the liner material 163, if any) of the tiers 164 of the stack structure 166 may define vertically extending strings of memory cells 168 coupled in series with one another within the stack structure 166. In some embodiments, the memory cells 168 formed at the intersections of the conductive material 162 (inclusive of the liner material 163, if any) and the cell pillar structures 130 within different tiers 164 of the stack structure 166 comprise so-called “MONOS” (metal-oxide-nitride-oxide-semiconductor) memory cells. In additional embodiments, the memory cells 168 comprise so-called “TANOS” (tantalum nitride-aluminum oxide-nitride-oxide-semiconductor) memory cells, or so-called “BETANOS” (band/barrier engineered TANOS) memory cells, each of which are subsets of MONOS memory cells. In further embodiments, the memory cells 168 comprise so-called “floating gate” memory cells including floating gates (e.g., metallic floating gates) as charge storage structures. The floating gates may horizontally intervene between central structures of the cell pillar structures 130 and the conductive material 162 of the different tiers 164 of the stack structure 166.

The additional dielectric fill material 170 of the slot structure 172 may be formed of and include at least one dielectric material, such as one or more of at least one dielectric oxide material, at least one dielectric nitride material, at least one dielectric oxynitride material, and at least one dielectric carboxynitride material. The additional dielectric fill material 170 may be substantially homogeneous, or the additional dielectric fill material 170 may be heterogeneous. In some embodiments, the additional dielectric fill material 170 is formed of and includes dielectric oxide material, such as SiOₓ (e.g., SiO₂).

Thus, in accordance with embodiments of the disclosure, a method of forming a microelectronic device includes in situ forming a boron-doped semiconductor material over a sacrificial material. A preliminary stack structure is formed over the boron-doped semiconductor material. The preliminary stack structure includes tiers respectively including additional sacrificial material and insulative material vertically neighboring the additional sacrificial material. Cell pillar structures are formed to respectively vertically extend through the preliminary stack structure, the boron-doped semiconductor material, and the sacrificial material. Slots are formed to respectively vertically extend through the preliminary stack structure and the boron-doped semiconductor material. The sacrificial material and portions of the cell pillar structures are replaced with lateral contact material by way of the slots. The lateral contact material contacts semiconductor material of remaining portions of the cell pillar structures. The additional sacrificial material of the tiers of the preliminary stack structure is replaced with conductive material after replacing the sacrificial material and the portions of the cell pillar structures with the lateral contact material.

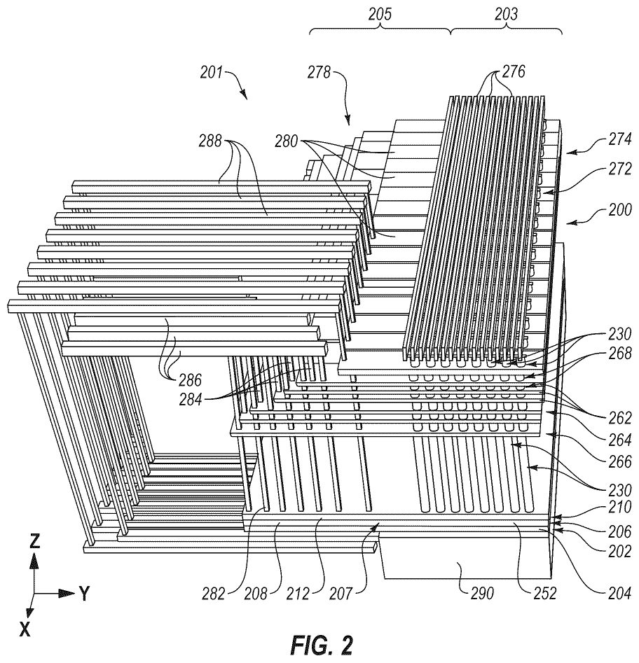

FIG. 2 illustrates a partial cutaway perspective view of a portion of a microelectronic device 201 (e.g., a memory device, such as a 3D NAND Flash memory device) including a microelectronic device structure 200. The microelectronic device structure 200 may be substantially similar to the microelectronic device structure 100 following the processing stage previously described with reference to FIG. 1L. In some embodiments, the microelectronic device structure 200 is formed through the processes previously described herein with reference to FIG. 1A through FIG. 1L. To avoid repetition, not all features (e.g., structures, materials, regions, devices) shown in FIG. 2 are described in detail herein. Rather, unless described otherwise below, in FIG. 2, a feature designated by a reference numeral that is a 100 increment of the reference numeral of a feature previously described with reference to one or more of FIG. 1A through FIG. 1L will be understood to be substantially similar to the previously described feature. In addition, for clarity and ease of understanding the drawings and associated description, some features of the microelectronic device structure 100 following the processing stage previously described with reference to FIG. 1L are not shown in FIG. 2. However, it will be understood that any features of the microelectronic device structure 100 following the processing stage previously described with reference to FIG. 1L may be included in the microelectronic device structure 200 of the microelectronic device 201 described herein with reference to FIG. 2.

As shown in FIG. 2, the slot structures 272 may divide the stack structure 266 into multiple blocks 274 separated from one another by the slot structures 272. The blocks 274 may horizontally alternate with the slot structures 272 in the X-direction and may horizontally extend in parallel with one another in the Y-direction orthogonal to the X-direction. Furthermore, the stack structure 266 may include a memory array region 203, and a staircase region 205 horizontally neighboring the memory array region in the Y-region. Within the memory array region 203, the blocks 274 may respectively include an array of the cell pillar structures 230 (and, hence, an array of the vertically extending strings of memory cells 268). Within the staircase region 205, the blocks 274 may respectively include at least one staircase structure 278 having steps 280 defined by horizontal ends of the tiers 264 of the stack structure 266. Within an individual block 274 of the stack structure 266, the steps 280 of the staircase structure 278 of the block 274 may serve as contact locations for the conductive material 262 of the tiers 264.

Still referring to FIG. 2, within the lateral contact tier 206, the microelectronic device structure 200 of the microelectronic device 201 may include at least one etch resistant material 207. The etch resistant material 207 may vertically underlie (e.g., in the Z-direction) and horizontally overlap (i.e., in the X-direction, in the Y-direction) portions of the slot structures 272 within the staircase region 205 of the stack structure 266. The etch resistant material 207 may be omitted from (e.g., not formed within) the horizontal area of the memory array region 203 of the stack structure 266. For an individual slot structure 272, the etch resistant material 207 may also partially horizontally overlap, in the Y-direction, two (2) of the blocks 274 horizontally neighboring the slot structure 272 in the Y-direction; and may substantially horizontally extend, in the X-direction, across portions of two (2) of the blocks 274 within the staircase region 205. Portions of the boron-doped semiconductor material 212 of the capping tier 210 within the staircase region 205 of the stack structure 266 may vertically overlie and horizontally overlap (e.g., in the X-direction, in the Y-direction) the etch resistant material 207.

The etch resistant material 207 of the lateral contact tier 206 may be relatively more resistant to removal than the sacrificial material 208 of the lateral contact tier 206 during common (e.g., collective, mutual) exposure to an etchant (e.g., an etching agent, such as a wet etching agent). Accordingly, during the material removal process previously described herein with reference to FIG. 1H, the etch resistant material 207 may not be substantially removed. The etch resistant material 207 maintained within the lateral contact tier 206 may protect portions of the sacrificial material 208 horizontally adjacent thereto from being removed during the material removal process. Circumventing the removal of portions of the sacrificial material 208 within the staircase region 205 may mitigate stresses otherwise effectuating undesirable damage and/or undesirable deformations within the microelectronic device 201. As a result, within the lateral contact tier 206 of the microelectronic device 201, the sacrificial material 208 may be present within a horizontal area of the staircase region 205 of the stack structure 266, and the lateral contact material 252 may be present within a horizontal area of the memory array region 203 of the stack structure 266. Within a horizontal area of an individual block 274 of the stack structure 266, the sacrificial material 208 of the lateral contact tier 206 may vertically underlie and horizontally overlap (e.g., in the X-direction, in the Y-direction) the staircase structure 278 of the block 274; and the lateral contact material 252 of the lateral contact tier 206 may vertically underlie and horizontally overlap (e.g., in the X-direction, in the Y-direction) the array of vertically extending strings of memory cells 268 within the block 274.

The etch resistant material 207 of the lateral contact tier 206 may be formed by doping portions of the sacrificial material 208 of the lateral contact tier 206 with at least one dopant (e.g., chemical species) that modifies the etch resistance of the doped portions of the sacrificial material 208 relative to other portions of the sacrificial material 208. The portions of the sacrificial material 208 may be doped (e.g., implanted) with the dopant prior to the formation (e.g., in situ formation) of the boron-doped semiconductor material 112 of the capping tier 110. The doped portions of the sacrificial material 208 may constitute the etch resistant material 207. The dopant may be selected at least partially based on the material composition of the sacrificial material 208, so as to enhance the etch resistance of the doped portions of sacrificial material 208 forming the etch resistant material 207 relative to other portions of the sacrificial material 208 remaining undoped with the dopant. As a non-limiting example, if the sacrificial material 208 comprises polycrystalline silicon, the portions of the sacrificial material 208 may be doped with at least one P-type dopant (e.g., one or more of B, Al, and Ga) to form the etch resistant material 207. In some embodiments, the P-type dopant is B. The etch resistant material 207 (e.g., doped polycrystalline silicon) may, for example, have greater etch resistance to TMAH than remaining portions of the sacrificial material 208 not doped with the P-type dopant. In some embodiments, the etch resistant material 207 of the lateral contact tier 206 comprises boron-doped polycrystalline silicon.

Still referring to FIG. 2, the microelectronic device 201 may further include digit lines 276 (e.g., data lines, bit lines), step contact structures 284, access line routing structures 286, and select line routing structures 288. The step contact structures 284 may contact (e.g., physically contact, electrically contact) the steps 280 of the staircase structures 278 within the staircase region 204 of the microelectronic device 201, and may couple components to one another as shown (e.g., the select line routing structures 288 to the conductive material 262 of some of the tiers 264 (e.g., upper ones of the tiers 264) of the stack structure 266 employed as upper select gates (e.g., SGDs); the access line routing structures 286 to the conductive material 262 of some others of the tiers 264 of the stack structure 266 employed as local access lines). Additional contact structures 282 may vertically extend through the blocks 274 of the stack structure 266 and may be employed as one or more of support structures and signal routing structures. In addition, as shown in FIG. 2, at least a portion of a base structure 290 is positioned within horizontal boundaries of the memory array region 203 of the microelectronic device 201. The base structure 290 may include a control logic region including control logic circuitry (e.g., CMOS circuitry) that may be coupled to the vertically extending strings of memory cells 268. In such embodiments, the control logic region of the base structure 290 may be characterized as having a “CMOS under Array” (“CuA”) configuration.

Thus, in accordance with embodiments of the disclosure, a microelectronic device includes a boron-doped semiconductor material, a stack structure, slot structures, and cell pillar structures. The boron-doped semiconductor material is vertically above a lateral contact material. The stack structure is vertically above the boron-doped semiconductor material and includes blocks horizontally extending in parallel in a first direction and individually having tiers respectively including conductive material and insulative material vertically neighboring the conductive material. The slot structures vertically extend through the stack structure, the boron-doped semiconductor material, and the lateral contact material. The slot structures horizontally alternate with the blocks of the stack structure in a second direction orthogonal to the first direction. The cell pillar structures respectively include semiconductor material in contact with the lateral contact material and vertically extending through each of the lateral contact material, the boron-doped semiconductor material, and the stack structure.

Furthermore, in accordance with embodiments of the disclosure, a memory device includes a stack structure, a capping tier vertically underlying the stack structure, a lateral contact tier vertically underlying the capping tier, and dielectric slot structures. The stack structure includes blocks including tiers each comprising conductive material vertically neighboring insulative material. The blocks respectively include a memory array region including strings of memory cells vertically extending through some of the tiers, and a staircase region horizontally neighboring the memory array region in a first direction and comprising a staircase structure having steps comprising horizontal ends of the tiers. The capping tier includes boron-doped polycrystalline silicon including greater than or equal to about 1.0E15 boron atoms/cm³. The lateral contact tier includes lateral contact material coupled to the strings of memory cells. The dielectric slot structures are horizontally interposed between the blocks of the stack structure in a second direction orthogonal to the first direction. The dielectric slot structures vertically extend through and physically contact each of the stack structure, the boron-doped polycrystalline silicon of the capping tier, and the lateral contact material of the lateral contact tier.

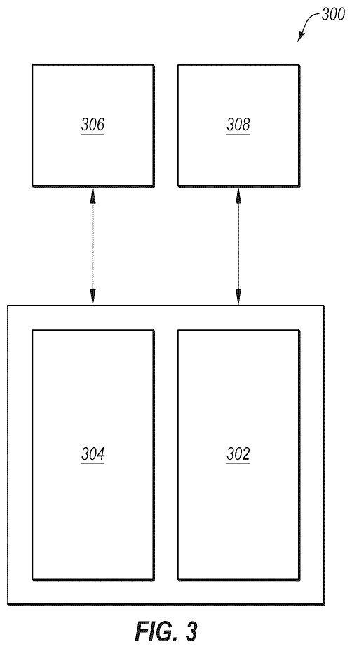

Microelectronic devices (e.g., the microelectronic device 201 (FIG. 2)) and microelectronic device structures (e.g., the microelectronic device structure 100 (FIG. 1L)) in accordance with embodiments of the disclosure may be used in embodiments of electronic systems of the disclosure. For example, FIG. 3 is a block diagram of an illustrative electronic system 300 according to embodiments of disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 300 includes at least one memory device 302. The memory device 302 may comprise, for example, one or more of a microelectronic device (e.g., the microelectronic device 201 (FIG. 2)) and a microelectronic device structure (e.g., the microelectronic device structure 100 (FIG. 1L)) previously described herein. The electronic system 300 may further include at least one electronic signal processor device 304 (often referred to as a “microprocessor”). The electronic signal processor device 304 may, optionally, include one or more of a microelectronic device (e.g., the microelectronic device 201 (FIG. 2)) and a microelectronic device structure (e.g., the microelectronic device structure 100 (FIG. 1L)) previously described herein. While the memory device 302 and the electronic signal processor device 304 are depicted as two (2) separate devices in FIG. 3, in additional embodiments, a single (e.g., only one) memory/processor device, having the functionalities of the memory device 302 and the electronic signal processor device 304, is included in the electronic system 300. In such embodiments, the memory/processor device may include one or more of a microelectronic device (e.g., the microelectronic device 201 (FIG. 2)) and a microelectronic device structure (e.g., the microelectronic device structure 100 (FIG. 1L)) previously described herein. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, a speaker, etc. In some embodiments, the input device 306 and the output device 308 comprise a single touchscreen device that can be used both to input information to the electronic system 300 and to output visual information to a user. The input device 306 and the output device 308 may communicate electrically with one or more of the memory device 302 and the electronic signal processor device 304.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A microelectronic device, comprising:
a boron-doped semiconductor material vertically above a lateral contact material;
a stack structure vertically above the boron-doped semiconductor material and comprising blocks horizontally extending in parallel in a first direction and individually having tiers respectively including conductive material and insulative material vertically neighboring the conductive material;
slot structures vertically extending through the stack structure, the boron-doped semiconductor material, and the lateral contact material, the slot structures horizontally alternating with the blocks of the stack structure in a second direction orthogonal to the first direction; and
cell pillar structures respectively comprising semiconductor material in contact with the lateral contact material and vertically extending through each of the lateral contact material, the boron-doped semiconductor material, and the stack structure.

2. The microelectronic device of claim 1, wherein the boron-doped semiconductor material comprises greater than or equal to about 1.0E15 boron atoms per cubic centimeter (cm³).

3. The microelectronic device of claim 1, wherein an atomic concentration range of boron in the boron-doped semiconductor material is within a range of from about 1.0E20 boron atoms/cm³ to about 3.0E21 boron atoms/cm³.

4. The microelectronic device of claim 3, within the boron-doped semiconductor material comprises boron-doped polycrystalline silicon.

5. The microelectronic device of claim 1, wherein portions of side surfaces of the slot structures directly physically contact the boron-doped semiconductor material.

6. The microelectronic device of claim 5, wherein the boron-doped semiconductor material further directly physically contacts a charge-blocking material of respective ones of the cell pillar structures, the charge-blocking material horizontally surrounding the semiconductor material.

7. The microelectronic device of claim 1, wherein the slot structures respectively comprise:
a first portion vertically extending through the stack structure and having a first vertical cross-sectional shape;
a second portion vertically extending through the boron-doped semiconductor material and having a second vertical cross-sectional shape different than the first vertical cross-sectional shape of the first portion; and
a third portion vertically extending through the lateral contact material and having a third vertical cross-sectional shape different than each of the second vertical cross-sectional shape of the second portion and the first vertical cross-sectional shape of the first portion.

8. The microelectronic device of claim 7, wherein the second portion of respective ones of the slot structures comprises:
an upper end outwardly horizontally projecting from a lower boundary of the first portion;
a lower end having a smaller horizontal cross-sectional area than the upper end; and
a side surfaces extending from and between the upper end and the lower end, the side surfaces individually acutely angled relative to the upper end.

9. The microelectronic device of claim 7, wherein the slot structures respectively further comprise:
a dielectric liner within each of the second portion and the third portion thereof, the dielectric liner:
on and substantially covering side surfaces of the lateral contact material; and
substantially covering lower portions of side surfaces of the boron-doped semiconductor material; and
a dielectric fill material within each of the first portion, the second portion, and the third portion thereof, the dielectric fill material:
on and substantially covering inner side surfaces of the dielectric liner;
on and substantially covering side surfaces of the stack structure; and
on and substantially covering upper portions of the side surfaces of the boron-doped semiconductor material.

10. The microelectronic device of claim 1, wherein the lateral contact material comprises additional semiconductor material.

11. A method of forming a microelectronic device, comprising:
in situ forming a boron-doped semiconductor material over a sacrificial material;
forming a preliminary stack structure over the boron-doped semiconductor material, the preliminary stack structure comprising tiers respectively including additional sacrificial material and insulative material vertically neighboring the additional sacrificial material;
forming cell pillar structures respectively vertically extending through the preliminary stack structure, the boron-doped semiconductor material, and the sacrificial material;
forming slots respectively vertically extending through the preliminary stack structure and the boron-doped semiconductor material;
replacing the sacrificial material and portions of the cell pillar structures with lateral contact material by way of the slots, the lateral contact material contacting semiconductor material of remaining portions of the cell pillar structures; and
replacing the additional sacrificial material of the tiers of the preliminary stack structure with conductive material after replacing the sacrificial material and the portions of the cell pillar structures with the lateral contact material.

12. The method of claim 11, wherein in situ forming a boron-doped semiconductor material over a sacrificial material comprises forming boron-doped polycrystalline silicon through chemical vapor deposition, the boron-doped polycrystalline silicon comprising greater than or equal to about 1.0E15 boron atoms/cm³.

13. The method of claim 11, further comprising, before forming the preliminary stack structure:
forming openings vertically extending through the boron-doped semiconductor material to the sacrificial material;
forming dielectric liners within the openings; and
forming etch stop structures on the dielectric liners within the openings.

14. The method of claim 13, wherein forming slots respectively vertically extending through the preliminary stack structure and the boron-doped semiconductor material comprises:
forming initial slots vertically extending through the preliminary stack structure and to the etch stop structures; and
selectively removing the etch stop structures by way of the initial slots to form the slots.

15. The method of claim 11, further comprising forming dielectric liners within the slots prior to replacing the sacrificial material and the portions of the cell pillar structures with the lateral contact material.

16. The method of claim 15, wherein replacing the sacrificial material and the portions of the cell pillar structures with lateral contact material comprises:
removing portions of the dielectric liners at bottoms of the slots to expose the portions of the sacrificial material;
selectively removing the sacrificial material by way of the slots after removing the portions of the dielectric liners at the bottoms of the slots;
removing portions of charge-blocking material, charge-trapping material, and tunnel dielectric material of the cell pillar structures after selectively removing the sacrificial material to partially expose semiconductor material of the cell pillar structures and form a void space underlying the boron-doped semiconductor material; and
filling the void space with the lateral contact material.

17. The method of claim 16, further comprising, before replacing the additional sacrificial material of the tiers of the preliminary stack structure with conductive material:
removing portions of the dielectric liners and the lateral contact material within horizontal areas of the slots to form enlarged slots, the enlarged slots respectively vertically extending through the preliminary stack structure, the boron-doped semiconductor material, and the lateral contact material; and
forming a dielectric oxide liner on surfaces of remaining portions of the lateral contact material exposed by the enlarged slots.

18. The method of claim 17, further comprising filling the enlarged slots with dielectric material after replacing the additional sacrificial material of the tiers of the preliminary stack structure with the conductive material.

19. The method of claim 11, further comprising doping portions of the sacrificial material with boron to form regions of etch resistant material within the sacrificial material prior to in situ forming the boron-doped semiconductor material.

20. A memory device, comprising:
a stack structure comprising blocks including tiers each comprising conductive material vertically neighboring insulative material, the blocks respectively comprising:
a memory array region including strings of memory cells vertically extending through some of the tiers; and
a staircase region horizontally neighboring the memory array region in a first direction and comprising a staircase structure having steps comprising horizontal ends of the tiers;
a capping tier vertically underlying the stack structure and comprising boron-doped polycrystalline silicon including greater than or equal to about 1.0E15 boron atoms/cm³;
a lateral contact tier vertically underlying the capping tier and comprising lateral contact material coupled to the strings of memory cells; and
dielectric slot structures horizontally interposed between the blocks of the stack structure in a second direction orthogonal to the first direction, the dielectric slot structures vertically extending through and physically contact each of the stack structure, the boron-doped polycrystalline silicon of the capping tier, and the lateral contact material of the lateral contact tier.
